(19) United States
(12) Patent Application Publication
(10) Pub. No.: US 2024/0105426 A1
(43) Pub. Date: Mar. 28, 2024

(54) SHOWERHEAD AND SUBSTRATE PROCESSING APPARATUS INCLUDING THE SAME

(71) Applicant: SAMSUNG ELECTRONICS CO., LTD., Suwon-si (KR)

(72) Inventor: Hyungsik KO, Suwon-si (KR)

(73) Assignee: SAMSUNG ELECTRONICS CO., LTD., Suwon-si (KR)

(21) Appl. No.: 18/209,641

(22) Filed: Jun. 14, 2023

(30) Foreign Application Priority Data
Sep. 23, 2022 (KR) 10-2022-0121106
Feb. 3, 2023 (KR) 10-2023-0015187

(51) Int. Cl. H01J 37/32

(52) U.S. Cl. CPC H01J 37/3244; H01J 37/32724; H01J 2237/2007

(57) ABSTRACT

A showerhead includes an inner plate including at least one gas hole that penetrates the inner plate in a first direction, and an outer plate at least partially surrounding the inner plate, the outer plate having a ring shape with an axis that extends in the first direction, where the outer plate includes a first inner surface that extends downward and forms an acute angle with a line corresponding to the first direction, a first bottom surface that extends outward from the first inner surface, and a first outer surface that extends upward from the first bottom surface, and where a first angle between the first inner surface and a line corresponding to the first direction is greater than a second angle between the first outer surface of the outer plate and a line corresponding to the first direction.

### CROSS-REFERENCE TO RELATED APPLICATIONS

This application is based on and claims priority to Korean Patent Application No. 10-2023-0015187, filed on Feb. 3, 2023, in the Korean Intellectual Property Office, and Korean Patent Application No. 10-2022-0121106, filed on Sep. 23, 2022, in the Korean Intellectual Property Office, the disclosures of which are incorporated herein by reference in their entireties.

### BACKGROUND

### 1. Field

Example embodiments of the disclosure relate to a showerhead and a substrate processing apparatus including the same, and more particularly, to a showerhead capable of preventing a substrate from contamination and a substrate processing apparatus including the same.

### 2. Description of Related Art

A semiconductor device may be fabricated by using various processes. For example, a semiconductor device may be manufactured by allowing a silicon wafer to undergo a photolithography process, an etching process, a deposition process, and so forth. Various fluids may be used in such processes. For example, plasma may be used in an etching process and/or a deposition process. An electrode may be used to form and/or control the plasma during process.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a showerhead capable of preventing inward movement of external particles and inducing outward movement of internal particles, and a substrate processing apparatus including the same.

One or more example embodiments provide a showerhead capable of preventing a substrate from contamination and a substrate processing apparatus including the same.

One or more example embodiments provide a showerhead capable of increasing a lifetime of components to increase a maintenance period, and a substrate processing apparatus including the same.

Additional aspects will be set forth in part in the description which follows and, in part, will be apparent from the description, or may be learned by practice of the presented embodiments.

According to an aspect of an example embodiment, a showerhead may include an inner plate including at least one gas hole that penetrates the inner plate in a first direction, and an outer plate at least partially surrounding the inner plate, the outer plate having a ring shape with an axis that extends in the first direction, where the outer plate may include a first inner surface that extends downward and forms an acute angle with a line corresponding to the first direction, a first bottom surface that extends outward from the first inner surface, and a first outer surface that extends upward from the first bottom surface, and where a first angle between the first inner surface and a line corresponding to the first direction may be greater than a second angle between the first outer surface of the outer plate and a line corresponding to the first direction.

According to an aspect of an example embodiment, a substrate processing apparatus may include a showerhead, and an outer ring that at least partially surrounds the showerhead, where the showerhead may include an inner plate that including a plurality of gas holes and where a bottom surface of the inner plate may be at a level lower than a level of a bottom surface of the outer ring.

According to an aspect of an example embodiment, a substrate processing apparatus may include a showerhead, an outer ring that at least partially surrounds the showerhead, and a heating liner ring that at least partially surrounds the outer ring, where the showerhead may include an inner plate that includes a gas hole and an outer plate that at least partially surrounds the inner plate, where the outer ring may include quartz, and the heating liner ring comprises a material that is different from a material of the outer ring.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a substrate processing apparatus according to some embodiments of the disclosure;

FIG. 2 is an enlarged cross-sectional view illustrating section X of FIG. 1 according to some embodiments of the disclosure;

FIG. 3 is a diagram illustrating a substrate processing apparatus according to some embodiments of the disclosure;

FIG. 4 is a diagram illustrating a substrate processing apparatus according to some embodiments of the disclosure;

FIG. 5 is an enlarged cross-sectional view illustrating section Y of FIG. 1 according to some embodiments of the disclosure;

FIG. 6 is a cross-sectional view illustrating a showerhead according to some embodiments of the disclosure;

FIG. 7 is a cross-sectional view illustrating a showerhead according to some embodiments of the disclosure;

FIG. 8 is a cross-sectional view illustrating a substrate processing apparatus according to some embodiments of the disclosure;

FIG. 9 is a bottom view illustrating a showerhead according to some embodiments of the disclosure;

FIG. 10 is an enlarged bottom view illustrating section Z of FIG. 9 according to some embodiments of the disclosure;

FIG. 11 is a flowchart illustrating a substrate processing method according to some embodiments of the disclosure; and

FIGS. 12, 13, 14, 15 and 16 are cross-sectional views illustrating the substrate processing method according to the flowchart of FIG. 11 according to some embodiments of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

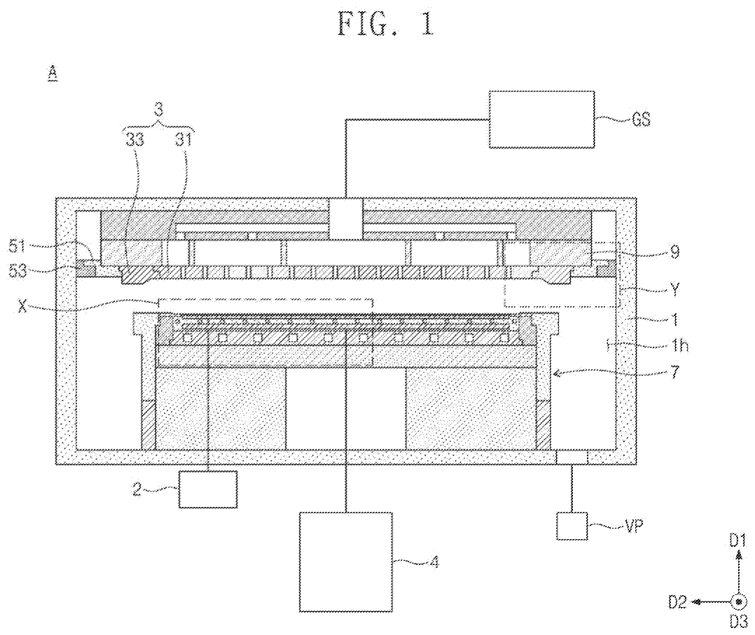

FIG. 1 is a cross-sectional view illustrating a substrate processing apparatus according to some embodiments of the disclosure.

Throughout the disclosure, D1 may indicate a first direction, D2 may indicate a second direction that intersects the first direction D1, and D3 may indicate a third direction that intersects each of the first direction D1 and the second direction D2. The first direction D1 may be referred to as a vertical direction. Each of the second direction D2 and the third direction D3 may be referred to as a horizontal direction.

Referring to FIG. 1, a substrate processing apparatus A may be provided. The substrate processing apparatus A may be configured to allow a substrate to undergo an etching process and/or a deposition process. A term “substrate” may refer to a silicon (Si) wafer, but the disclosure is not limited thereto. The substrate processing apparatus A may use plasma to treat a substrate. The substrate processing apparatus A may generate plasma in various ways. For example, the substrate processing apparatus A may be a capacitively coupled plasma (CCP) apparatus and/or an inductively coupled plasma (ICP) apparatus. A CCP type substrate processing apparatus is described herein but the embodiments are not limited thereto. The substrate processing apparatus A may include a process chamber 1, a stage 7, a showerhead 3, an outer ring 51, a heating liner ring 53, a direct-current (DC) power generator 2, a radio-frequency (RF) power generator 4, a vacuum pump VP, and a gas supply device GS.

The process chamber 1 may include a process space 1h. A substrate process may be performed in the process space 1h. The process space 1h may be separated from an external space. The process space 1h may be in a substantial vacuum state during a substrate process. The process chamber 1 may have a cylindrical shape, but the disclosure is not limited thereto.

The stage 7 may be positioned in the process chamber 1. For example, the stage 7 may be positioned in the process space 1h. The stage 7 may support and/or fix a substrate. A substrate process may be performed in a state where a substrate is placed on the stage 7. The stage 7 will be further described below.

The showerhead 3 may be positioned in the process chamber 1. For example, the showerhead 3 may be positioned in the process space 1h. The showerhead 3 may be disposed to be upwardly spaced apart from the stage 7. A gas supplied from the gas supply device GS may be uniformly sprayed through the showerhead 3 into the process space 1h. The showerhead 3 may include an inner plate 31 and an outer plate 33. The inner plate 31 and the outer plate 33 may be separable from each other. For example, the inner plate 31 and the outer plate 33 may be separate components from each other. The showerhead 3 will be further described in detail below.

The outer ring 51 may surround or at least partially surround the showerhead 3. For example, outside the showerhead 3 when viewed in plan, the outer ring 51 may surround or at least partially surround the showerhead 3. The outer ring 51 may contact the showerhead 3. The outer ring 51 may include quartz. The outer ring 51 will be further described in detail below.

The heating liner ring 53 may surround or at least partially surround the outer ring 51. For example, in a plan view, outside the outer ring 51, the heating liner ring 53 may surround or at least partially surround the outer ring 51. The heating liner ring 53 may support the outer ring 51. The heating liner ring 53 may include a different material from that of the outer ring 51. For example, the heating liner ring 53 may include aluminum (Al) and yttrium (Y₂O₃). In more detail, yttrium (Y₂O₃) may be coated on aluminum (Al) to form the heating liner ring 53. The heating liner ring 53 will be further described in detail below.

The DC power generator 2 may apply a DC power to the stage 7. The DC power applied from the DC power generator 2 may rigidly place a substrate on a certain position on the stage 7.

The RF power generator 4 may supply a RF power to the stage 7. Thus, plasma in the process space 1h may be controlled. A detailed description thereof will be further described below.

The vacuum pump VP may be connected to the process space 1h. The vacuum pump VP may apply a vacuum pressure to the process space 1h during a substrate process.

The gas supply device GS may supply a gas to the process space 1h. The gas supply device GS may include a gas tank, a compressor, and a valve. The plasma may be generated from a portion of gas supplied from the gas supply device GS to the process space 1h.

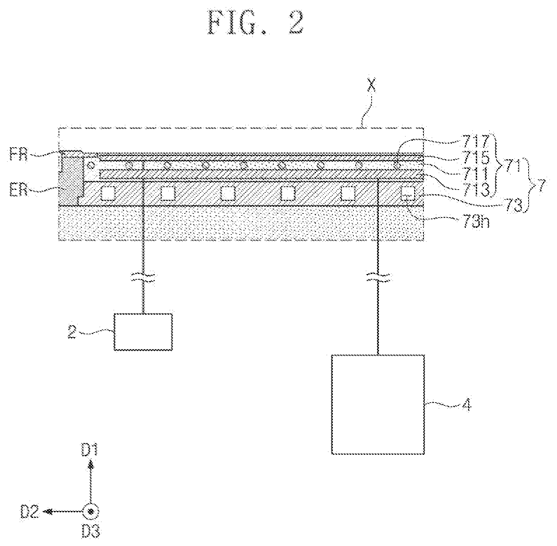

FIG. 2 is an enlarged cross-sectional view illustrating section X of FIG. 1 according to some embodiments of the disclosure.

Referring to FIG. 2, the stage 7 may include a chuck 71 and a cooling plate 73.

A substrate may be disposed on the chuck 71. The chuck 71 may fix a substrate on a position thereof. The chuck 71 may include a chuck body 711, a plasma electrode 713, a chuck electrode 715, and a heater 717.

The chuck body 711 may have a cylindrical shape. The chuck body 711 may include a ceramic, but the disclosure is not limited thereto. A substrate may be disposed on a top surface of the chuck body 711. The chuck body 711 may be surrounded or at least partially surrounded by a focus ring FR and/or an edge ring ER.

The plasma electrode 713 may be positioned in the chuck body 711. The plasma electrode 713 may include aluminum (Al). The plasma electrode 713 may have a disk shape, but the disclosure is not limited thereto. The plasma electrode 713 may be provided with a RF power. For example, the RF power generator 4 may apply the RF power to the plasma electrode 713. The RF power applied to the plasma electrode 713 may control plasma in the process space (see 1h of FIG. 1).

The chuck electrode 715 may be positioned in the chuck body 711. The chuck electrode 715 may be positioned higher than the plasma electrode 713. The chuck electrode 715 may be supplied with a DC power. For example, the DC power generator 2 may apply the DC power to the chuck electrode 715. The DC power applied to the chuck electrode 715 may rigidly place a substrate on a position on the chuck body 711. The chuck electrode 715 may include aluminum (Al), but the disclosure is not limited thereto.

The heater 717 may be positioned in the chuck body 711. The heater 717 may be positioned between the chuck electrode 715 and the plasma electrode 713. The heater 717 may include a hot wire. For example, the heater 717 may include a concentrically circular shaped hot wire. The heater 717 may radiate heat to the surrounding environment. Therefore, the chuck body 711 may have an increased temperature.

The cooling plate 73 may be positioned below the chuck 71. For example, the chuck 71 may be positioned on the cooling plate 73. The cooling plate 73 may provide a cooling hole 73h. Cooling water may flow in the cooling hole 73h. The cooling water in the cooling hole 73h may absorb heat from the cooling plate 73.

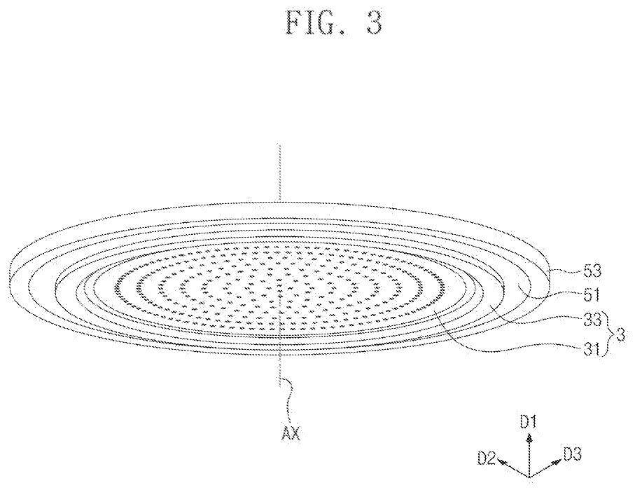

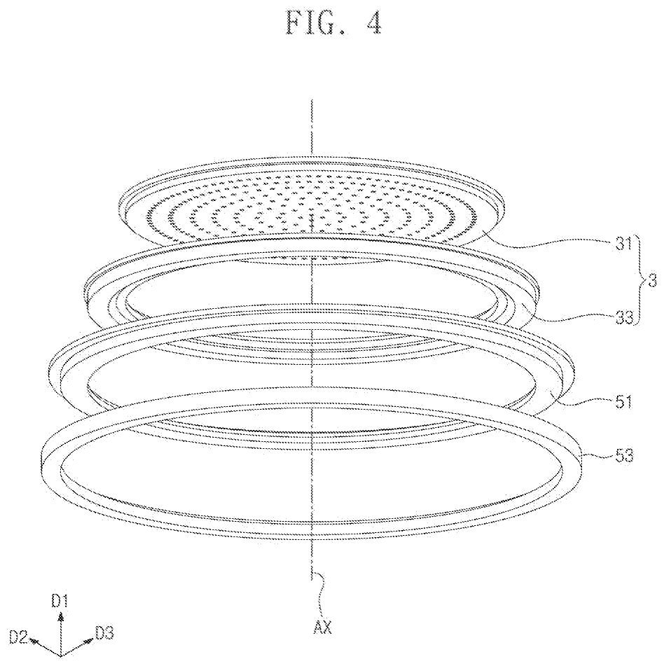

FIG. 3 is a diagram illustrating a substrate processing apparatus according to some embodiments of the disclosure. FIG. 4 is a diagram illustrating a substrate processing apparatus according to some embodiments of the disclosure. FIG. 5 is an enlarged cross-sectional view illustrating section Y of FIG. 1 according to some embodiments of the disclosure.

Referring to FIGS. 3, 4, and 5, the showerhead 3 may include the inner plate 31 and the outer plate 33.

The inner plate 31 may have a disk shape having an axis AX that extends in the first direction D1. The inner plate 31 may include a gas hole 31h. The gas hole 31h may extend in the first direction D1 to penetrate the inner plate 31. The inner plate 31 may include a plurality of gas holes (e.g., including gas hole 31h). The plurality of gas holes may be spaced apart from each other in the horizontal direction. A single gas hole 31h is be described, but the disclosure is not limited thereto. The gas hole 31h will be further described in detail below. The inner plate 31 may include silicon (Si) and/or silicon carbide (SiC), but the disclosure is not limited thereto. The inner plate 31 will be further described in detail below.

The outer plate 33 may surround or at least partially surround the inner plate 31. For example, in a plan view, the outer plate 33 may surround the inner plate 31 (e.g., positioned around the inner plate 31). The outer plate 33 may have a ring shape. For example, the outer plate 33 may have a ring shape having an axis AX that extends in the first direction D1. The outer plate 33 may therefore have a rotational body that rotates about the axis AX. The outer plate 33 may include silicon (Si) and/or silicon carbide (SiC), but the disclosure is not limited thereto. The outer plate 33 will be further described in detail below.

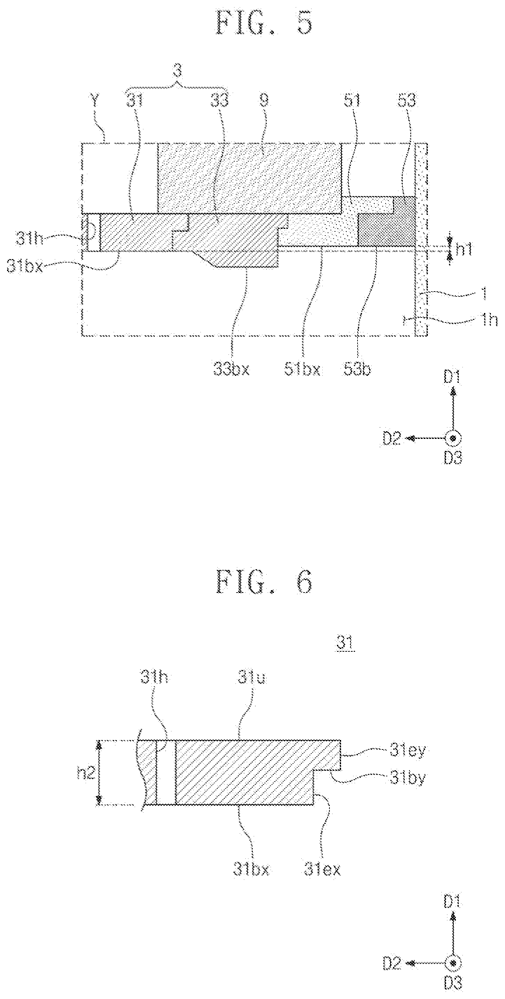

FIG. 6 is a cross-sectional view illustrating a showerhead according to some embodiments of the disclosure.

Referring to FIG. 6, the inner plate 31 may have a top surface 31u, a bottom surface 31bx, a first outer surface 31ex, a protruding bottom surface 31by, and a second outer surface 31ey. A minimum distance between the top surface 31u and the bottom surface 31bx of the inner plate 31 may be a thickness h2 of the inner plate 31. The thickness h2 of the inner plate 31 may range from about 11 mm to about 13 mm. For example, the thickness h2 of the inner plate 31 may be about 12 mm. The first outer surface 31ex may extend upward from an edge of the bottom surface 31bx of the inner plate 31. The protruding bottom surface 31by may extend outward from an upper end of the first outer surface 31ex. The protruding bottom surface 31by may be located at a higher level than that of the bottom surface 31bx of the inner plate 31. No hole may be provided on the protruding bottom surface 31by. The second outer surface 31ey may extend upward from an edge of the protruding bottom surface 31by. The second outer surface 31ey may be connected to the top surface 31u of the inner plate 31.

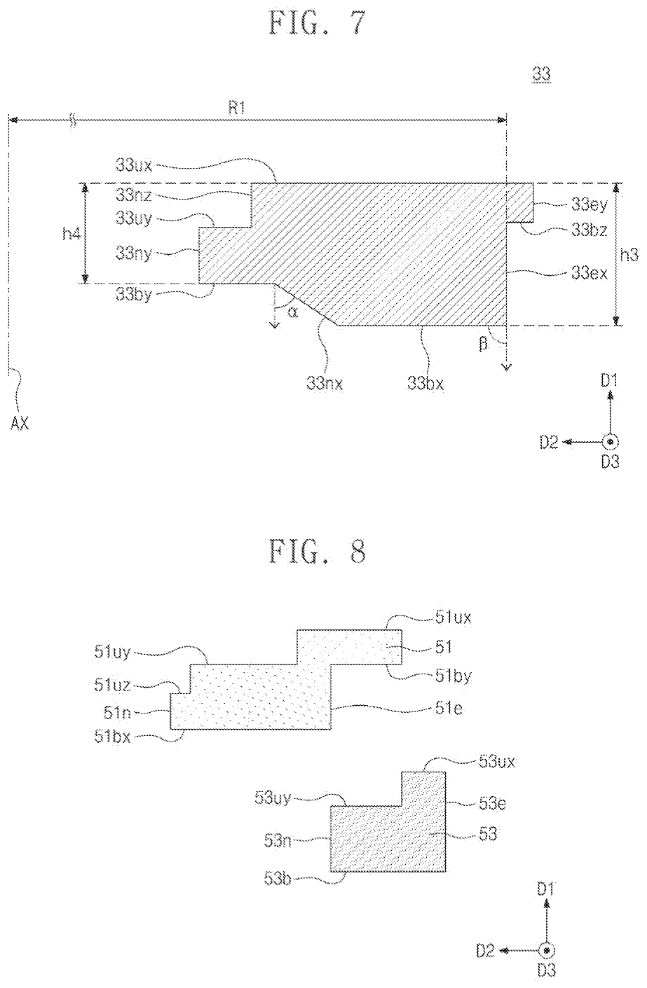

FIG. 7 is a cross-sectional view illustrating a showerhead according to some embodiments of the disclosure.

Referring to FIG. 7, the outer plate 33 may have a first inner surface 33nx, a first bottom surface 33bx, a first outer surface 33ex, a second bottom surface 33by, a second inner surface 33ny, a protruding top surface 33uy, a third inner surface 33nz, a top surface 33ux, a second outer surface 33ey, and a connection bottom surface 33bz.

The first inner surface 33nx may extend downward while making an acute angle with the first direction D1 (e.g., forming an acute angle with a line corresponding to the first direction D1). For example, a first angle α may be made between the first inner surface 33nx and the first direction D1. The first angle α may be an acute angle. The first angle α may range from about 45° to about 65°. For example, the first angle α may be about 55°.

The first bottom surface 33bx may extend outward from the first inner surface 33nx. The first bottom surface 33bx may be perpendicular to the first direction D1. The first bottom surface 33bx may be connected to the first outer surface 33ex. For example, the first bottom surface 33bx may connect the first inner surface 33nx to the first outer surface 33ex. As illustrated in FIG. 5, the first bottom surface 33bx may be located at a lower level than that of the bottom surface 31bx of the inner plate 31.

The first outer surface 33ex may extend upward from the first inner surface 33nx. A second angle, or 90°−β (i.e., 90 degrees minus β), may be refer to an angle made between the first outer surface 33ex and the first direction D1 (e.g., an angle between the first outer surface 33ex and a line corresponding to the first direction D1). The second angle 90°−β may be less than the first angle α. For example, the first angle α may be greater than the second angle 90°−β. The second angle 90°−β may be equal to or less than about 10°. For example, the second angle 90°−β may be about 0° For example, the first outer surface 33ex may be parallel to the first direction D1. The first outer surface 33ex may be perpendicular to the first bottom surface 33bx. The first outer surface 33ex may be defined by a vertical line.

A first radius R1 may refer to a radius of the first outer surface 33ex. The first radius R1 may be, for example, equal to or greater than about 150 mm. For example, the first outer surface 33ex may have a diameter of equal to or greater than about 300 mm. The first radius R1 may be, for example, in a range of about 175 mm to about 225 mm.

The second bottom surface 33by may extend inward from the first inner surface 33nx. The second bottom surface 33by may be perpendicular to the first direction D1.

The second inner surface 33ny may extend upward from the second bottom surface 33by. The second inner surface 33ny may be parallel to the first direction D1. The second inner surface 33ny may contact the inner plate (see 31 of FIG. 6). For example, the second inner surface 33ny may contact the first outer surface (see 31ex of FIG. 6) of the inner plate (see 31 of FIG. 6).

The protruding top surface 33uy may extend outward from an upper end of the second inner surface 33ny. The protruding top surface 33uy may be perpendicular to the first direction D1. No hole may be provided on the protruding top surface 33uy.

The third inner surface 33nz may extend upward from the protruding top surface 33uy. The third inner surface 33nz may be parallel to the first direction D1. The third inner surface 33nz may be connected to the top surface 33ux of the outer plate 33.

The top surface 33ux of the outer plate 33 may extend outward from an upper end of the third inner surface 33nz. The top surface 33ux of the outer plate 33 may be perpendicular to the first direction D1.

A distance between the top surface 33ux and the first bottom surface 33bx of the outer plate 33 may be referred to as a first thickness h3 of the outer plate 33. The first thickness h3 may range from about 15 mm to about 19 mm. For example, the first thickness h3 may be about 17 mm.

A distance between the top surface 33ux and the second bottom surface 33by of the outer plate 33 may be referred to as a second thickness h4 of the outer plate 33. The second thickness h4 may be less than the first thickness h3. The second thickness h4 may range from about 11 mm to about 13 mm. For example, the second thickness h4 may be about 12 mm. The second thickness h4 may be substantially the same as or similar to the thickness (see h2 of FIG. 6) of the inner plate (see 31 of FIG. 6).

The second outer surface 33ey may extend downward from the top surface 33ux of the outer plate 33. The second outer surface 33ey may be parallel to the first direction D1.

The connection bottom surface 33bz may extend inward from a lower end of the second outer surface 33ey. The connection bottom surface 33bz may be perpendicular to the first direction D1. The connection bottom surface 33bz may be connected to the first outer surface 33ex. For example, the connection bottom surface 33bz may connect the second outer surface 33ey to the first outer surface 33ex.

FIG. 8 is a cross-sectional view illustrating a substrate processing apparatus according to some embodiments of the disclosure.

Referring to FIG. 8, the outer ring 51 may have an inner surface 51n, a first bottom surface 51bx, an outer surface 51e, a second bottom surface 51by, a first top surface 51ux, a second top surface 51uy, and a third top surface 51uz.

The inner surface 51n of the outer ring 51 may extend in the first direction D1. As illustrated in FIG. 5, the inner surface 51n of the outer ring 51 may contact the first outer surface (see 31ex of FIG. 7).

The first bottom surface 51bx of the outer ring 51 may extend outward from the inner surface 51n of the outer ring 51.

The outer surface 51e of the outer ring 51 may extend outward from an edge of the first bottom surface 51bx of the outer ring 51.

The second bottom surface 51by of the outer ring 51 may extend outward from an upper end of the outer surface 51e of the outer ring 51.

The first top surface 51ux of the outer ring 51 may be perpendicular to the first direction D1. As illustrated in FIG. 5, the first top surface 51ux of the outer ring 51 may be located at a level substantially the same as that of the top surface (see 31u of FIG. 6) of the inner plate 31. For example, the first top surface 51ux of the outer ring 51 may be positioned on the same plane of the top surface (see 31u of FIG. 6) of the inner plate 31.

The second top surface 51uy of the outer ring 51 may be perpendicular to the first direction D1. The second top surface 51uy of the outer ring 51 may be located at a lower level than that of the first top surface 51ux of the outer ring 51.

The third top surface 51uz of the outer ring 51 may be perpendicular to the first direction D1. The third top surface 51uz of the outer ring 51 may be located at a lower level than that of the second top surface 51uy of the outer ring 51. The third top surface 51uz of the outer ring 51 may be connected to the inner surface 51n of the outer ring 51.

The heating liner ring 53 may have a bottom surface 53b, an outer surface 53e, a first top surface 53ux, a second top surface 53uy, and an inner surface 53n.

The bottom surface 53b of the heating liner ring 53 may be perpendicular to the first direction D1.

The outer surface 53e of the heating liner ring 53 may extend upward from an edge of the bottom surface 53b of the heating liner ring 53.

The first top surface 53ux of the heating liner ring 53 may extend inward from the outer surface 53e of the heating liner ring 53.

The second top surface 53uy of the heating liner ring 53 may be perpendicular to the first direction D1. The second top surface 53uy of the heating liner ring 53 may contact the second bottom surface 51by of the outer ring 51. The second top surface 53uy of the heating liner ring 53 may be located at a lower level than that of the first top surface 53ux of the heating liner ring 53.

The inner surface 53n of the heating liner ring 53 may extend in the first direction D1. The inner surface 53n of the heating liner ring 53 may contact the outer surface 51e of the outer ring 51.

Referring back to FIG. 5, the protruding bottom surface (see 31by of FIG. 6) of the inner plate 31 may contact the protruding top surface (see 33uy of FIG. 7) of the outer plate 33. For example, the protruding bottom surface (see 31by of FIG. 6) of the inner plate 31 may contact a surface of the protruding top surface (see 33uy of FIG. 7) of the outer plate 33.

The bottom surface 31bx of the inner plate 31 may be located at a level substantially the same as or similar to that of the second bottom surface (see 33by of FIG. 7) of the outer plate 33. For example, the bottom surface 31bx of the inner plate 31 may be positioned on the same plane of the second bottom surface (see 33by of FIG. 7) of the outer plate (see 33 of FIG. 7).

The bottom surface 31bx of the inner plate 31 may be located at a lower level than that of the first bottom surface 51bx of the outer ring 51. A first gap h1 may be defined to refer to a difference in level between the bottom surface 31bx of the inner plate 31 and the first bottom surface 51bx of the outer ring 51. The first gap h1 may range from about 1 mm to about 3 mm. For example, the first gap h1 may be about 2 mm.

The first outer surface (see 33ex of FIG. 7) of the outer plate 33 may be connected to the first bottom surface 51bx of the outer ring 51. For example, the first outer surface 33ex of the outer plate 33 may meet the first bottom surface 51bx of the outer ring 51.

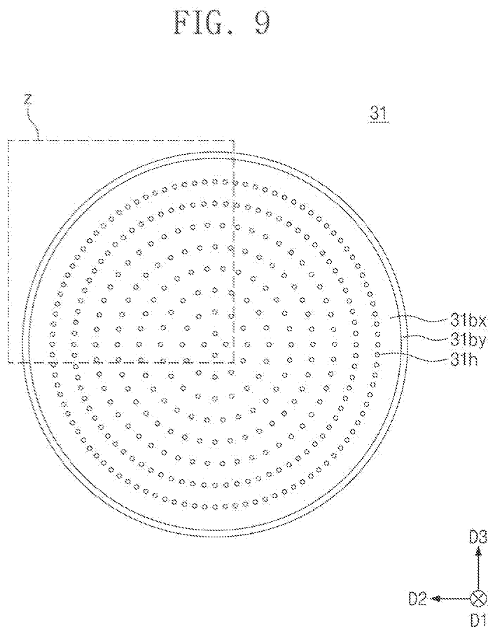

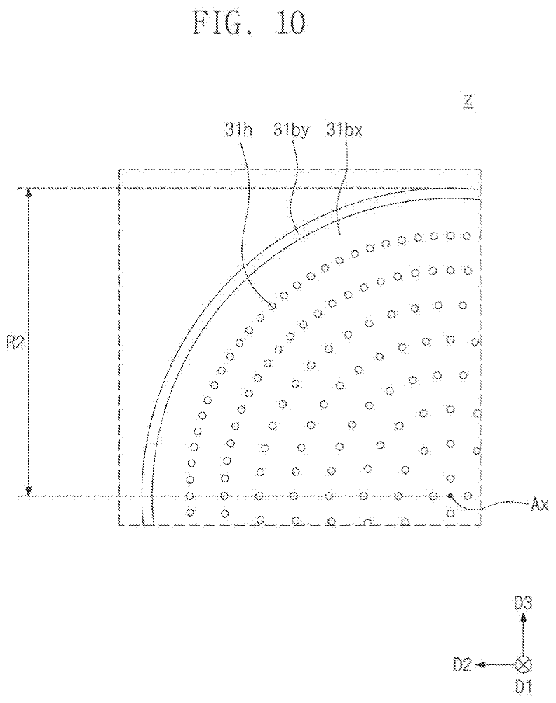

FIG. 9 is a bottom view illustrating a showerhead according to some embodiments of the disclosure. FIG. 10 is an enlarged bottom view illustrating section Z of FIG. 9 according to some embodiments of the disclosure.

Referring to FIGS. 9 and 10, the inner plate 31 may include a plurality of gas holes 31h. The number of the plurality of gas holes 31h may be between 300 to 410. A second radius R2 may be refer to a radius of the inner plate 31. The second radius R2 may range from about 150 mm to about 175 mm.

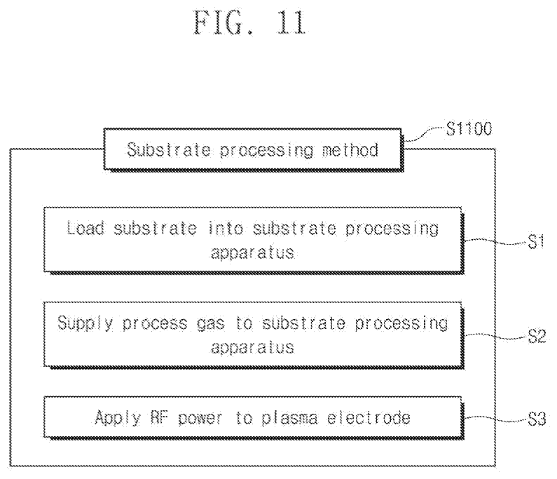

FIG. 11 is a flowchart illustrating a substrate processing method according to some embodiments of the disclosure.

Referring to FIG. 11, a substrate processing method S1100 is shown. The substrate processing method S1100 may be a method of treating a substrate by using the substrate processing apparatus (see A of FIG. 1) described with reference to FIGS. 1 to 10. The substrate processing method S1100 may include loading a substrate into a substrate processing apparatus in operation Si, supplying a process gas into the substrate processing apparatus in operation S2, and applying a RF power to a plasma electrode in operation S3.

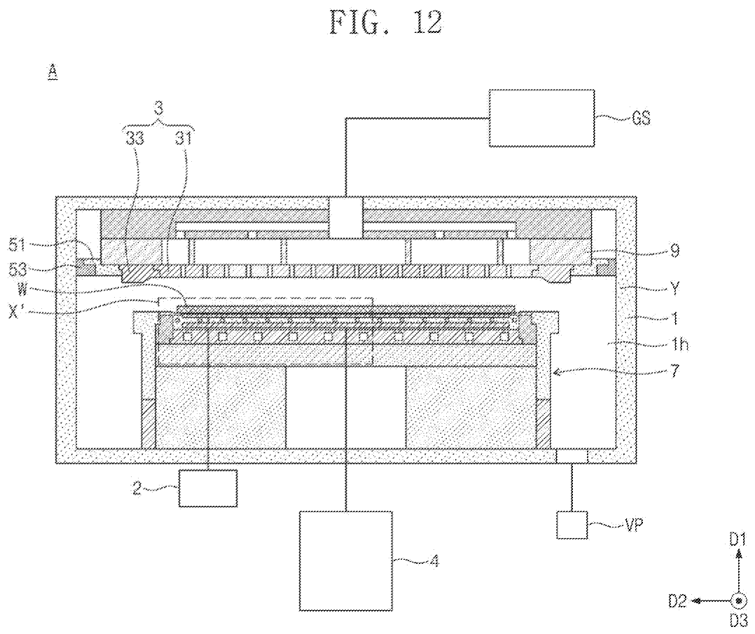

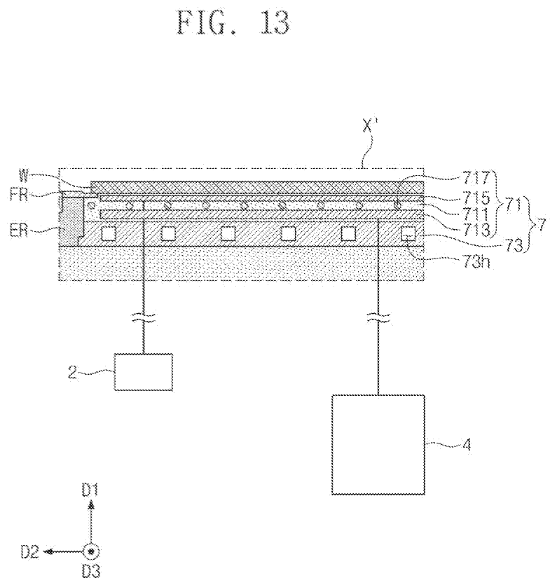

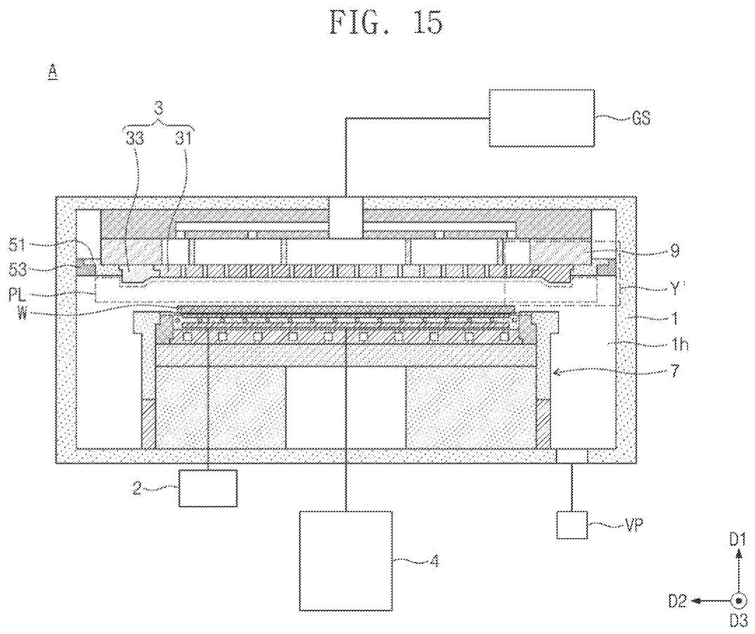

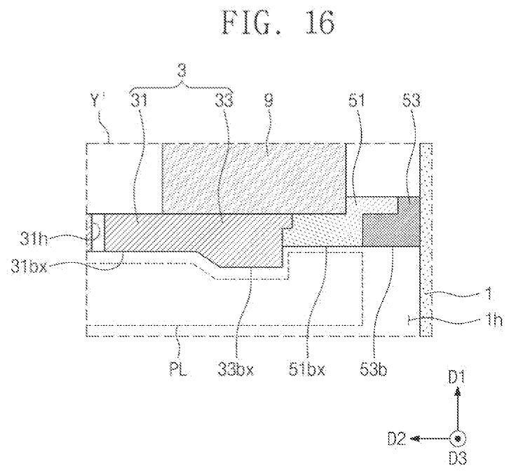

A substrate processing method of FIG. 11 will be described in detail below with reference to FIGS. 12 to 16.

FIGS. 12, 13, 14, 15 and 16 are cross-sectional views illustrating the substrate processing method according to the flowchart of FIG. 11 according to some embodiments of the disclosure.

Referring to FIGS. 11, 12, and 13, the substrate loading operation 51 may include placing a substrate W on the stage 7. When the DC power generator 2 applies a direct-current (DC) voltage to the chuck electrode 715, the substrate W may be fixed on a certain position on the chuck body 711.

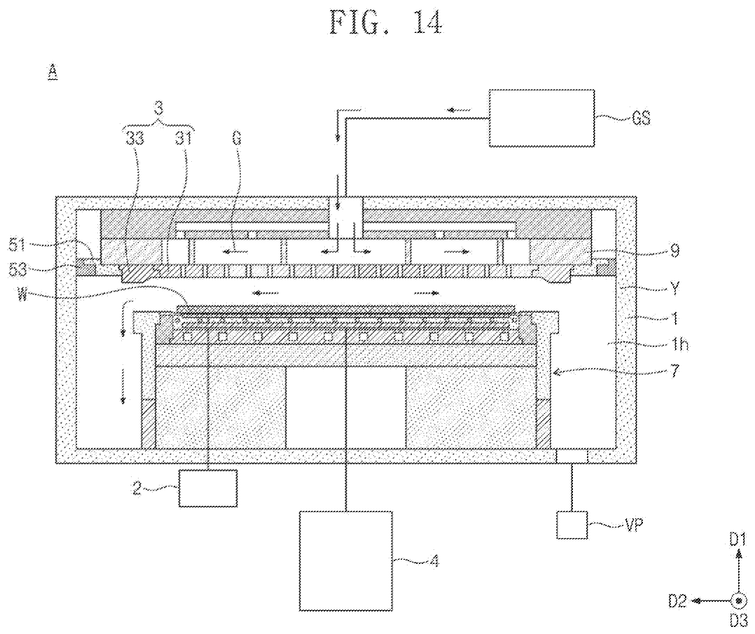

Referring to FIGS. 11 and 14, the gas supply operation S2 may include allowing the gas supply device GS to supply a process gas G to the process space 1h, or supplying the process gas G to the process space 1h. The process gas G may be distributed through the showerhead 3 onto the substrate W.

Referring to FIGS. 11, 15, and 16, the power apply operation S3 may include allowing the RF power generator 4 to apply a RF power to the stage 7, or applying a RF power to the stage 7. When the RF power is applied to the plasma electrode (see 713 of FIG. 13), a portion of the process gas (see G of FIG. 14) in the process space 1h may be converted into plasma PL. The plasma PL may treat the substrate W on the stage 7.

According to a showerhead and a substrate processing apparatus including the same in accordance with some embodiments of the disclosure, an outer plate may have a first inner surface that is outwardly inclined. Thus, particles attached to a bottom surface of an inner plate may outwardly migrate along the first inner surface. In addition, the outer plate may have a first outer surface whose slope is greater than that of the first inner surface. The first outer surface may block movement of particles onto the inner plate from a bottom surface of an outer ring to which the particles are attached. Therefore, particles on a bottom surface of the showerhead may be outwardly deflected. The particles on the bottom surface of the showerhead may thus be prevented from falling downwards onto a substrate during process. The substrate may be thus be prevented from contamination. Thus, a yield of substrate etching may be increased.

According to a showerhead and a substrate processing apparatus including the same in accordance with some embodiments of the disclosure, an inner plate may have a bottom surface positioned on the same plane of a second bottom surface of an outer plate. In addition, a first outer surface of the outer plate may be connected to a bottom surface of an outer ring. Thus, particles on the bottom surface of the inner plate may move to the outer ring sequentially through the second bottom surface, a first inner surface, and a first bottom surface of the outer plate.

According to a showerhead and a substrate processing apparatus including the same in accordance with some embodiments of the disclosure, an outer ring may include quartz. The quartz may maintain its relatively low temperature during process. Particles may be favorably attached to a material whose temperature is low. Therefore, particles attached to a bottom surface of the outer ring may be prevented from moving back to a bottom surface of the showerhead.

According to a showerhead and a substrate processing apparatus including the same in accordance with some embodiments of the disclosure, a bottom surface of the showerhead may be located at a lower level than that of a bottom surface of an outer ring. Plasma formed below the showerhead may be outwardly spread due to being vertically pressed. Therefore, the plasma may be uniformly distributed. Accordingly, a yield with respect to an edge region of a substrate may be increased.

According to a showerhead and a substrate processing apparatus including the same in accordance with some embodiments of the disclosure, the showerhead may be divided into two components. Thus, a component that requires maintenance may be selectively replaced. For example, when an inner plate requires replacement due to wear, only the inner plate may be replaced without replacing an outer plate.

According to a showerhead and a substrate processing apparatus including the same in accordance with some embodiments of the disclosure, an inner plate may have an increased thickness. Thus, the inner plate may be used longer. A maintenance period may thus be increased.

According to a showerhead and a substrate processing apparatus including the same of the disclosure, inward movement of external particles may be prevented and outward movement of internal particles may be induced.

According to a showerhead and a substrate processing apparatus including the same of the disclosure, contamination of a substrate may be prevented.

According to a showerhead and a substrate processing apparatus including the same of the disclosure, a maintenance period may be increased.

Effects of the disclosure is not limited to the mentioned above, other effects which have not been mentioned above will be clearly understood to those skilled in the art from the following description.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A showerhead, comprising:
an inner plate comprising at least one gas hole that penetrates the inner plate in a first direction; and
an outer plate at least partially surrounding the inner plate, the outer plate having a ring shape with an axis that extends in the first direction,
wherein the outer plate comprises:
a first inner surface that extends downward and forms an acute angle with a line corresponding to the first direction;
a first bottom surface that extends outward from the first inner surface; and
a first outer surface that extends upward from the first bottom surface, and
wherein a first angle between the first inner surface and a line corresponding to the first direction is greater than a second angle between the first outer surface of the outer plate and a line corresponding to the first direction.

2. The showerhead of claim 1, wherein the outer plate further comprises:
a second inner surface contacting the inner plate; and
a second bottom surface that extends outward from the second inner surface and is connected to the first inner surface,
wherein the second bottom surface is at a level that is substantially the same as a level of a first bottom surface of the inner plate, and
wherein the second bottom surface is on a plane that is substantially the same as a plane of the first bottom surface of the inner plate.

3. The showerhead of claim 2, wherein the inner plate further comprises:
a first outer surface that extends upward from an edge of the first bottom surface of the inner plate;
a protruding bottom surface that extends outward from an upper end of the first outer surface of the inner plate;
a second outer surface that extends upward from an edge of the protruding bottom surface and is connected to a top surface of the inner plate,
wherein the outer plate further comprises:
a protruding top surface that extends upward from an upper end of the second inner surface; and
a third inner surface that extends upward from an outer edge of the protruding top surface and is connected to a first top surface of the outer plate, and
wherein the protruding bottom surface contacts the protruding top surface.

4. The showerhead of claim 3, wherein no hole is provided on each of the protruding bottom surface and the protruding top surface.

5. The showerhead of claim 1, wherein the first angle is in a range of about 45° to about 65°.

6. The showerhead of claim 1, wherein the inner plate comprises a plurality of gas holes, the at least one gas hole being among the plurality of gas holes, and
wherein the plurality of gas holes is 300 gas holes to 410 gas holes.

7. The showerhead of claim 1, wherein the second angle is equal to or less than about 10°.

8. The showerhead of claim 1, wherein a diameter of the first outer surface of the outer plate is equal to or greater than about 300 mm.

9. A substrate processing apparatus, comprising:
a showerhead; and
an outer ring that at least partially surrounds the showerhead,
wherein the showerhead comprises an inner plate that comprising a plurality of gas holes,
wherein a bottom surface of the inner plate is at a level lower than a level of a bottom surface of the outer ring.

10. The substrate processing apparatus of claim 9, wherein a thickness of the inner plate is in a range of about 11 mm to about 13 mm.

11. The substrate processing apparatus of claim 9, wherein the outer ring comprises quartz.

12. The substrate processing apparatus of claim 11, further comprising a heating liner ring that at least partially surrounds the outer ring,
wherein the heating liner ring comprises Y₂O₃.

13. The substrate processing apparatus of claim 9, wherein a top surface of the outer ring is at a level that is substantially the same as a level of a top surface of the inner plate.

14. The substrate processing apparatus of claim 9, wherein the showerhead further comprises an outer plate between the inner plate and the outer ring,
wherein the outer plate comprises:
a first inner surface that extends downward; and
a first bottom surface that extends outward from the first inner surface, and
wherein the first bottom surface is at a level that is lower than a level of the bottom surface of the inner plate.

15. A substrate processing apparatus, comprising:
a showerhead;
an outer ring that at least partially surrounds the showerhead; and
a heating liner ring that at least partially surrounds the outer ring,
wherein the showerhead comprises:
an inner plate comprising a gas hole; and
an outer plate that at least partially surrounds the inner plate,
wherein the outer ring comprises quartz, and
wherein the heating liner ring comprises a material that is different from a material of the outer ring.

16. The substrate processing apparatus of claim 15,
wherein the outer plate has a ring shape with an axis that extends in a first direction,
wherein the outer plate comprises:
a first inner surface that extends downward and forms an acute angle with a line corresponding to the first direction;
a first bottom surface that extends outward from the first inner surface; and
a first outer surface that extends upward from the first bottom surface, and
wherein an inner surface of the outer ring contacts the first outer surface.

17. The substrate processing apparatus of claim 15, wherein the heating liner ring comprises Y₂O₃.

18. The substrate processing apparatus of claim 15, further comprising:
a process chamber comprising a process space; and
a stage provided in the process chamber,
wherein the showerhead, the outer ring, and the heating liner ring are provided in the process chamber, and
wherein the showerhead is spaced apart from the stage in an upward direction.

19. The substrate processing apparatus of claim 15, wherein a bottom surface of the inner plate is at a level that is lower than a level of a bottom surface of the outer ring.

20. The substrate processing apparatus of claim 19, wherein a difference in level between the bottom surface of the inner plate and the bottom surface of the outer ring is in a range of about 1 mm to about 3 mm.
